(19) United States
(12) Patent Application Publication
(10) Pub. No.: US 2011/0132575 A1
(43) Pub. Date: Jun. 9, 2011

(54) Cleaning Industrial Heat Exchangers Through Utilization of Thicknenss Mode Ultrasonics

(76) Inventor: J. Michael Goodson, Skillman, NJ (US)

(21) Appl. No.: 12/723,506

(22) Filed: Mar. 12, 2010

Related U.S. Application Data
(60) Provisional application No. 61/267,230, filed on Dec. 7, 2009.
(60) Provisional application No. 61/290,091, filed on Dec. 24, 2009.
(60) Provisional application No. 61/290,785, filed on Dec. 29, 2009.

(51) Int. Cl. B08B 3/12; F28F 7/00; H01L 41/053

(52) U.S. Cl. 165/95; 134/1; 310/348

(57) ABSTRACT

Methods and apparatuses for cleaning heat exchangers and heat exchanger components utilizing thickness mode ultrasonics. Heat exchanger components are placed in a tank. The tank is filled with cleaning media. One or more thickness mode transducers are placed in the tank and the thickness mode transducers are operated to clean the tank. In further embodiments, one or more thickness mode transducers are integrated within a heat exchanger. The transducers are operated to clean the heat exchanger space and components located therein.

### CROSS-REFERENCE TO RELATED APPLICATIONS

This application claims priority to U.S. Provisional Applications 61/267,230, 61/290,091, and 61/290,785, which are hereby incorporated by reference.

### BACKGROUND

A heat exchanger is a device that transfers heat between two mediums. Depending on the type of heat exchanger, the two mediums might be separated by a wall (e.g. tubing, plates, etc.) Other times, there is no such separation and the two mediums are in direct contact. A wide variety of consumer and industrial applications range utilize heat exchangers. Industries that use heat exchangers include the chemical, fertilizer, food & dairy, organic batch processing, pharmaceutical, paper, and petrochemical industries, and oil and gas refineries.

Generally, an industrial system will require a heat exchanger wherever it is necessary to add or remove heat from a particular process or thing. This encompasses many possibilities. Accordingly, a plurality of heat exchangers might be used in a single system or even in a single process within a system. For instance, the oil industry uses heat exchangers for such varied applications as oil stabilization, gas compression, wastewater treatment, gas desulphurization, crude oil desalting, and closed loop cooling. Yet, within any one of these areas, such as oil stabilization, multiple heat exchangers perform a variety of tasks (e.g. crude oil interchanger, crude oil heater, crude oil cooler, etc.) Therefore, heat exchangers are vital to industry because they perform many necessary functions.

Another reason why heat exchangers are vital to industry is that they allow for the reclamation or redirection of energy. In a particular system, one process might require cooling while another process requires heating. Such a system can utilize a heat exchanger to direct heat from the process requiring cooling to the processes requiring heating. Reclaiming or reusing heat in this manner allows industry to save large amounts of money.

For a heat exchanger to provide a maximum benefit, it must operate at maximum efficiency. One key parameter of heat exchanger efficiency is the surface area of the interface between the two mediums that are exchanging heat. In oil and gas applications, too large of a physical interface can cause a significant accumulation of contaminates, which, as will be discussed further, are difficult to remove using conventional cleaning methods, such as high power sprays.

In a shell and tube heat exchanger, there is a plurality of tubes that act as heat transfer elements. The tubes contain the medium to be heated or cooled. A heat transfer medium is passed over the tubes, and heat is either removed or added to the medium within the tubes. By maximizing the surface area of the tubes (subject to the limiting factors discussed above), a maximum amount of heat transfer medium is brought into thermodynamic contact with the medium within the tubes. This leads to one significant problem associated with heat exchangers efficiency: Fouling. Fouling occurs when impurities or scale accumulates on heat exchanger transfer elements (e.g. the tubes or plates, in the case of a plate type heat exchanger). These impurities or scales interpose themselves between the medium within the heat transfer elements and the heat exchange medium and thus reduce the effective surface area of the interface between the mediums.

One example can be taken from the oil industry. Raw oil contains a significant amount of contaminates due to a number of reasons: The long distance oil travels during extraction; the combination of thick oils and thin oils; the sand and tar in the oil; and the transporting process from the well heads to the first stage refineries. In another example, industries that use river water as a cooling medium create fouling problems. River water contains biological impurities that can build up on heat transfer components. Regardless of the cause, heat exchangers need to be cleaned to reduce the effects of scaling and fouling.

For large industrial heat exchangers, however, cleaning is not an easy or inexpensive undertaking. In one method, high pressure washers, with PSI ratings of 5,000 to 10,000 per inch, are used to clean heat exchanger components. In the oil industry, cleaning a 20 foot section of a five foot in diameter heat exchanger with a pressure washer can require up to 11,000,000 gallons of water and eight days to complete the operation. The cost of recycling the water expended in the cleaning operation can be as high as $5,000,000 to $6,000,000 or higher depending on the environmental regulations of the country where the cleaning operation takes place. Furthermore, there is significant opportunity cost associated with the lost time during which the heat exchanger is off line.

Therefore, what is needed is a way to efficiently clean an industrial size heat exchanger while reducing the cost of cleaning associated with water reclamation.

### SUMMARY OF THE INVENTION

Ultrasonic cleaning, particularly with thickness mode ultrasonic transducers, provides a much more efficient way to clean industrial heat exchangers. Unfortunately, conventional industrial heat exchangers were not designed with ultrasonic cleaning in mind. Accordingly, embodiments herein provide for the immediate application of ultrasonics to clean industrial heat exchangers by the provision of novel tanks designed to accommodate industrial heat exchangers (and heat exchanger components) and apply ultrasonic energy to the heat exchangers through the novel utilization of thickness mode transducers.

In additional embodiments, novel heat exchanger designs are provided in which thickness mode ultrasonics is integrated directly into heat exchangers themselves. These novel heat exchangers effect superior cleaning due to the positioning of thickness mode transducers at optimal locations throughout the heat exchanger shell. The integration of ultrasonics within the heat exchanger design reduces the time between taking a heat exchanger off line and commencement of the cleaning process. The embodiments provided herein will both significantly reduce the industry cost for cleaning heat exchangers and the cost and waste of water in the cleaning process.

In one embodiment, a heat exchanger is provided. A shell defines a space and has a first end, a second end, and at least two opposing sides, wherein the shell is adapted to hold a cleaning media. A heat exchanger component is positioned within the space. At least one thickness mode transducer positioned within the space, wherein when the space holds a cleaning media, and the thickness mode transducer is capable of imparting ultrasonic energy to the heat exchanger component through the cleaning media.

In one embodiment, a method of cleaning a heat exchanger component is provided. A heat exchanger component is selected for cleaning. The heat exchanger component is placed in a tank. The tank is filled with a cleaning media. At least one thickness mode transducer is connected to the cleaning tank. The at least one thickness mode transducer is operated to clean the heat exchanger component.

In one embodiment, a method of cleaning a component through utilization of an ultrasonic cleaning unit is provided. The ultrasonic cleaning unit comprises a frame having a first end and a second end, two opposing sides, an opening positioned between the first side and second opposing sides, and at least one thickness mode transducer connected to the frame within the opening. The method comprises placing a component in a cleaning tank; filling the tank with cleaning media; positioning the frame within the cleaning tank; and operating the at least one thickness mode transducer to clean the component.

In one embodiment, a transducer immersion unit is provided. A frame comprising a sidewall having a first end, a second end, at least two opposing sides, and an axis extending through the first end and the second end is provided. An opening is defined in the sidewall. At least one thickness mode transducer is positioned on the frame within the opening.

In one embodiment, a method of cleaning a heat exchanger component is provided. At least one thickness mode ultrasonic energy generating device including an ultrasonic converter and a horn attached to the ultrasonic converter is selected. The horn is adapted to transmit ultrasonic energy from the converter and is selected to match a surface contour of the heat exchanger component. The heat exchanger component is placed in a cleaning tank filled with cleaning media. The thickness mode ultrasonic energy device is attached to an external shell of a heat exchanger component. The thickness mode ultrasonic energy generating device is actuated such that ultrasonic energy is directed from the horn to at least one portion of the heat exchanger component.

In one embodiment, a method of cleaning a heat exchanger tube is provided. At least one thickness mode ultrasonic energy generating device includes an ultrasonic converter and a horn attached to the ultrasonic converter. The horn is adapted to transmit ultrasonic energy from the converter. The horn is selected to fit within the heat exchanger tube. The heat exchanger tube is placed in a cleaning tank filled with cleaning media. The horn is positioned within the heat exchanger tube. The thickness mode ultrasonic energy generating device is actuated such that ultrasonic energy is directed throughout the heat exchanger tube.

### BRIEF DESCRIPTION OF THE DRAWINGS

FIG. 1 is a perspective view of a heat exchanger cleaning apparatus including a shell defining a fluid filled space having piezoelectric components positioned on the perimeter thereof and a heat exchanger element positioned therein.

FIG. 2A is a perspective view of an exemplary PushPull® piezoelectric transducer that can be utilized as a piezoelectric component in the heat exchanger cleaning apparatus of FIG. 1.

FIG. 2B is an enlarged view of an exemplary piezoelectric component, with a portion of the end cap cut away, that can be utilized at each end of the PushPull® piezoelectric transducer of FIG. 2A.

FIG. 3A is a perspective view of an exemplary immersible transducer that can be utilized as a piezoelectric component in FIG. 1.

FIG. 3B is top plan view of the immersible transducer of FIG. 3A.

FIG. 3C is a side view of the immersible transducer of FIG. 3A.

FIG. 4 is a cut away perspective view of an embodiment in which the shell referred to in FIG. 1 is a cleaning tank and the piezoelectric components comprise a plurality of the PushPull® piezoelectric transducers of FIGS. 2A-2B.

FIG. 5 is a perspective view of an embodiment in which the shell defines a circular tank and the piezoelectric components comprise a plurality of piezoelectric rods.

FIG. 6 is a perspective view of an embodiment wherein the shell defines a rectangular heat exchanger shell or casing and the piezoelectric components comprise a plurality of piezoelectric rods.

FIGS. 7A-7D show embodiments of the heat exchanger in FIG. 6 in which the piezoelectric components are arranged in alternative configurations.

FIG. 8 is a perspective view of an embodiment wherein the shell is a circular heat exchanger and the piezoelectric components include a plurality of piezoelectric rods positioned in parallel to a tube bundle of the heat exchanger.

FIG. 9A-9B show embodiments in which the piezoelectric components comprise one or more instances of an ultrasonic welding apparatus.

FIG. 10A is a cross sectional view of a circular heat exchanger.

FIG. 10B is a sectional view taken along line 10B-10B of FIG. 10A and shows a horn of a thickness mode piezoelectric component inserted into an end of a heat exchanger tube.

It should be understood that the invention is not limited in its application to the details of the construction and the arrangement of the components set forth in the following description or illustrated in the drawings. The invention is capable of other embodiments and of being practiced or of being carried out in various ways. Also, it is understood that the phraseology and terminology used herein is to describe and should not be regarded as limiting.

### DETAILED DESCRIPTION

The drawings depict various preferred embodiments for purposes of illustration only. One skilled in the art will recognize from the following discussion that alternative embodiments of the structures and methods illustrated herein may be employed without departing from the principles described herein.

The deficiencies outlined above with respect to conventional heat exchanger cleaning processes can be overcome through the novel employment of ultrasonics as set forth herein. Specifically, the inventor has found that employing thickness mode ultrasonics is a particularly novel and effective way to clean industrial heat exchangers. It should be noted, however, that one should not limit the scope of the present application solely to the use of thickness mode ultrasonic cleaning processes, as the present application encompasses the use of both radial mode and thickness mode ultrasonics.

Thickness mode ultrasonics generally refers to imparting ultrasonic energy through utilization of a transducer operating in thickness mode. In thickness mode, a piezoelectric transducer is excited by an alternating current driving signal that causes alternating expansion and contraction of the thickness of the transducer. The resultant ultrasonic energy is discharged as a powerful directional force that can effectively penetrate to the interior of even the most dense and thick heat exchangers and heat exchanger components.

In one embodiment, ultrasonic thickness mode transducers are attached or immersed in a fluid filled tank of sufficient size to accommodate an industrial size heat exchanger or heat exchanger component, such as at tube bundle. The thickness mode transducers are actuated to impart ultrasonic energy to the heat exchanger or heat exchanger component and remove or loosen the contaminants therefrom. In a further application, however, the inventor has discovered that ultrasonics can be utilized to create a new generation of heat exchangers: Heat exchangers that accommodate the integration of transducers within their very structure.

The integration of thickness mode transducers can be effected by redesigning or retrofitting the heat exchanger and either fixing or removably attaching ultrasonic transducers to the heat exchanger shell. It should be noted that removable attachment provides a particular benefit in that thickness mode transducers can be attached to the heat exchanger body at the time of cleaning and removed prior to the heat exchanger's core operational mode. This is significant because thickness mode transducers depolarize at high temperatures (e.g. 190 degrees F.) and have to be rebuilt. Thus, the ability to remove thickness mode transducers prior to high temperature operations increases their life and minimizes maintenance costs. The adoption by industry of the enhanced heat exchanger designs provided herein will impart significant savings, both in real cost and in efficiency. As a consequence, industrial operators will be able to clean their heat exchangers more often and increase corresponding throughput.

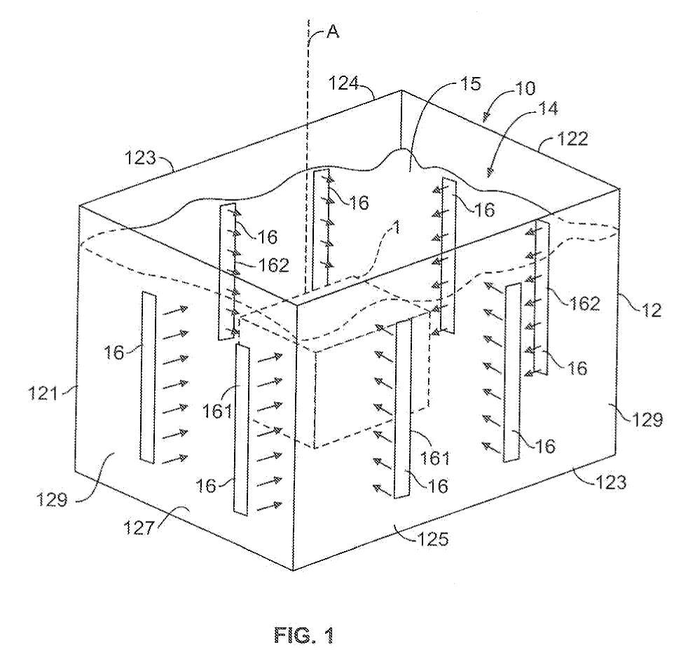

Referring now to FIG. 1, there is an exemplary apparatus 10 for cleaning a heat exchanger component 1. In one example, apparatus 10 comprises shell 12 having first end 121, second end 122, and two opposing sides 123. In a further example, two opposing sides 123 comprise a first side 124 and a second side 125. Shell 12 in one example also includes a bottom 127. In such example, first end 121, second end 122, opposing sides 123, and bottom 127 define a space 14. In FIG. 1, shell 12 and space 14 are shown as rectangular in cross-section for exemplary purposes. Shell and/or space 14 can take on other configurations, including but not limited to circular, square, oval, polygonal and the like. The particular configuration of space 14 is chosen according to criteria, such as the shape and dimension of heat exchanger component 1, the amount, shape and dimension of available transducer components, and to provide optimal cleaning properties to apparatus 10.

In use, space 14 is filled with fluid 15 that serves as a cleaning medium. Fluid 15 comprises any of a number of cleaning media of different chemistries, including water and alkaline cleaning solvents.

Referring further to FIG. 1, at least one instance of piezoelectric component 16, e.g. a thickness mode ultrasonic transducer, is positioned within space 14. Piezoelectric components 16 are electrically connected to one or more generators (not shown). The operator of the apparatus 10 actuates piezoelectric components 16 by controlling the application of electricity through the generator(s). Piezoelectric components 16 convert the electrical energy provided by the generator(s) to mechanical energy in the form of ultrasonic vibration. The ultrasonic vibration excites fluid 15 (e.g. in the general direction of the arrows shown in FIG. 1). Fluid 15 energized by ultrasonic energy causes contaminates on heat exchanger element 1 to stick together and move down, toward the direction of floor 127, thereby cleaning heat exchanger element 1. The process is assisted if the heat exchanger element 1 is manipulated (e.g. by tilting) to slope the various surfaces of heat exchanger element, thereby assisting in the movement of contaminates toward floor 127.

Piezoelectric transducers typically operate in two modes: One is thickness mode and the other is radial mode. Radial mode is the primary frequency mode for most ultrasonic cleaning and thickness mode is typically employed in ultrasonic welding. Thickness mode is also used for megasonic applications because there is no limitation as to frequency as the piezoelectric crystal elements get thinner. Thickness mode is determined by the frequency calculation of all the parts including the transducer elements that make up the transducer stack as compared to radial mode where the frequency is determined by the relationship between the inside and the outside diameter of a circular transducer crystal. Thickness mode calculations include the frequency of the total parts of the transducer stack. For example, metal has a frequency. One would take in consideration the frequency of the metal and to achieve the correct thickness frequency in metal to match the rest of the stack.

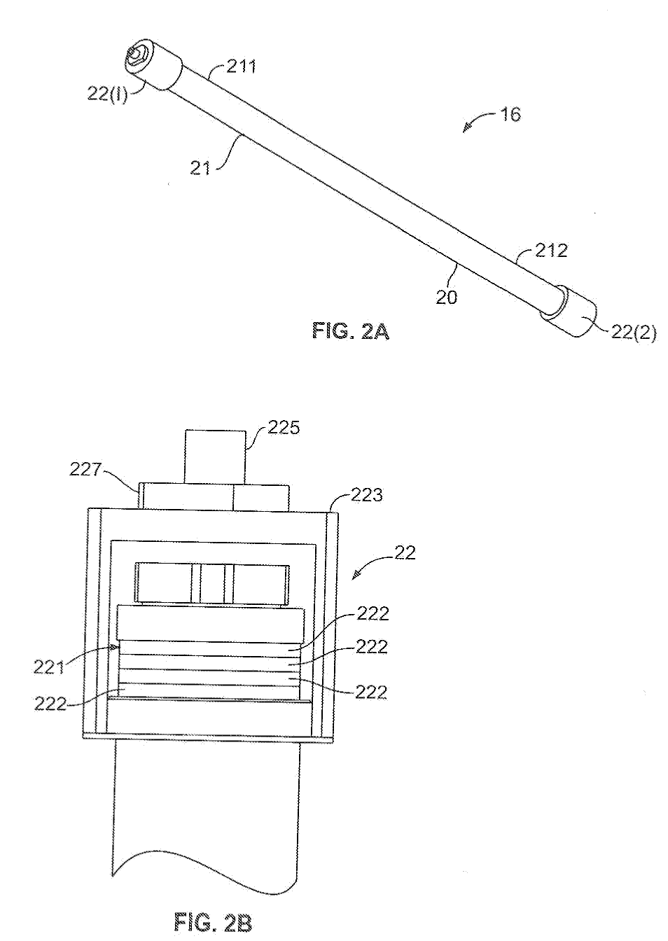

Piezoelectric component 16 in one example comprises a thickness mode transducer. Such a thickness mode transducer can include a number of possible transducer types. Referring to FIGS. 2A and 2B, in one example, piezoelectric component 16 comprises a PushPull® thickness mode transducer 20 of the kind manufactured by Martin Walter Ultraschalltechnik AG of Straubenhardt Germany. PushPull® transducer 20 is described in U.S. Pat. No. 5,200,666, which is hereby incorporated by reference. PushPull® thickness mode transducer 20 in one example comprises a rod 21 having a first end 211 and a second end 212. In one example, thickness mode transducer component 22(1) is positioned on first end 211. In another example, second thickness mode transducer component 22(2) is positioned on second end 212.

Referring to FIG. 2B, transducer component 22 in one example comprises thickness mode stacking 221 of transducer piezoelectric crystal elements 222. In one example, transducer elements 222 have a thickness of approximately two tenths (0.2) of an inch. Transducer elements 222 operating at thickness mode frequencies discharge their sound waves at a right angle to the plane of piezoelectric crystal elements 222. This provides a powerful directional force which optimally penetrates the interior of an object being cleaned, such as heat exchanger component 1 (FIG. 1). Thickness mode stacking 221 shown in FIG. 2B in one example is operated at frequencies within the range of 20 to 35 kHz. In another example, thickness mode stacking 221 is operated at frequencies greater than 35 kHz. Frequencies greater than 35 kHz can be especially helpful to remove stubborn contaminates. Thickness mode piezoelectric transducers are described in detail in U.S. Pat. No. 7,598,654, which is hereby incorporated by reference. It should be noted that the utilization of frequencies less than 20 kHz is also contemplated, but such lower frequencies may not always effectively clean the subject component, in which is case the frequency should be increased.

In another example, transducer elements 222 are configured in radial mode. Radial frequency in one example is created by configuring a transducer element as a disc with a hole located in its center. The size of the inner diameter relative to the outer diameter of the disc creates the radial frequency. The radius of the disc is inversely proportional to the frequency created. First harmonic radial transducers operate in the range of 15 to 65 kHz. Third harmonic radial transducers operate in the range of 250 to 300 kHz. A further description of radial mode transducers can be found in U.S. Pat. No. 5,748,566, which is hereby incorporated by reference.

Referring further to FIG. 2B, thickness mode transducer component 22 in one example includes an end cap 223 which serves to cover and protect piezoelectric elements 222. End cap 223 includes an interface 225, which is used to connect PushPull® thickness mode transducer 20 to a generator. In addition, end cap 223 includes a projection 227, which will described later herein, as being used to register with an opening on shell 12 to connect PushPull® thickness mode transducer 20 to shell 12.

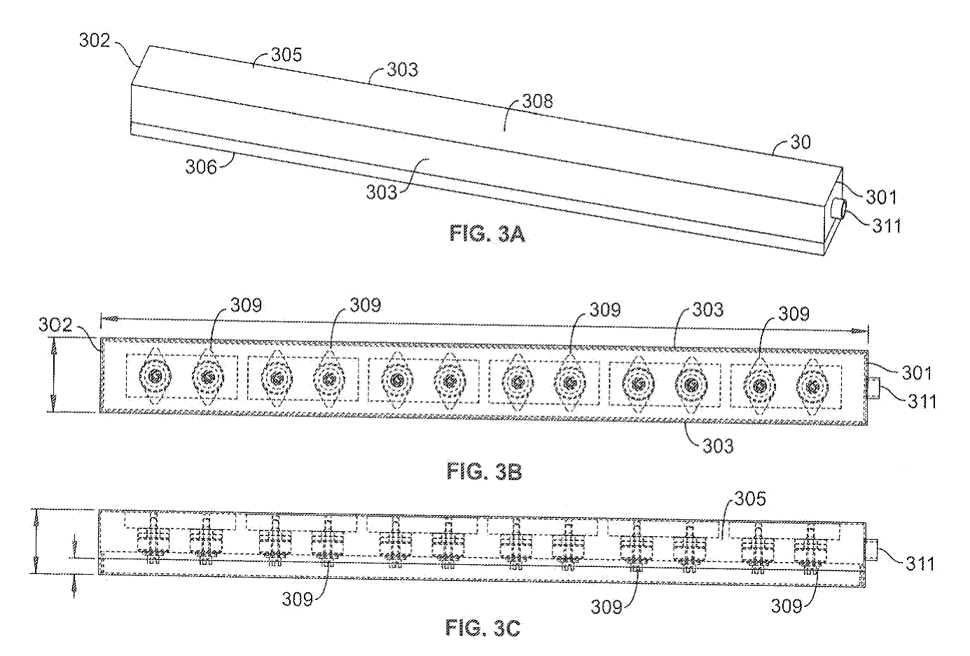

Referring to FIGS. 3A-3C, in another example, piezoelectric component 16 comprises an immersible thickness mode transducer 30. Immersible thickness mode transducer 30 comprises a first end 301, a second end 302, two opposing sides 303, a top side 305, and a bottom side 306, which define a space 308. Within the space 308 are one or more thickness mode piezoelectric components 309, which could alternatively be configured in radial mode. Immersible thickness mode transducer 30 includes an interface 311 for connecting transducer 30 to a generator. An exemplary immersible transducer is of the kind manufactured by Crest Ultrasonics Corp. of Trenton, N.J.

Referring further now to FIG. 1, piezoelectric components 16 in one example are attached to an interior surface of shell 12. The piezoelectric components 16 can be attached to the shell 12 through a variety of means, such as screws, bracketing, welding, adhesives, etc. In alternative embodiment, piezoelectric components 16 can simply be immersed in a free form manner into shell 12 and reside on the floor 127.

Piezoelectric components 16 can be arranged in a number of different configurations. For instance, in one embodiment, the piezoelectric components 16 can be arranged parallel with respect to a central axis A extending through space 14. In another embodiment, the piezoelectric components 16 can be arranged perpendicular to axis A. Other configurations, such as a combination of horizontally, vertically, and diagonally arranged piezoelectric components 16 are also possible.

The number of piezoelectric components 16 varies according to the application. In the example shown, piezoelectric components 16 are arranged in opposing pairs 161, 162 such that piezoelectric components are present on opposing sides 123 and end sides 129 (defined by first end 121, and second end 122). Alternatively, piezoelectric components 16 could be positioned only on one of opposing sides 123 or end sides 129. As another alternative, piezoelectric components 16 could be positioned only on one of sides 123, 129.

Heat exchanger component 1 in one example comprises an entire industrial shell and tube heat exchanger of the kind used in the chemical, fertilizer, food & dairy, organic batch processing, pharmaceutical, paper, petrochemical industries, and in oil and gas industries. Such heat exchangers can be as large as 24 feet long with a diameter of 2 to 6 feet. In another example, the heat exchanger 1 component comprises a subcomponent of a heat exchanger, such as a tube bundle (assembled or disassembled) or the heat exchanger shell. Tube bundles can comprise as many as 600 or more individual tubes. Accordingly, shell 12 must be large enough to hold such volume. To accommodate 600 heat exchanger tubes, an exemplary tank would have the following dimensions 6′W×7′H×20′L. To optimize the cleaning process of heat exchanger component 1, it is desirable to fill both the tubes and the shell 12 with cleaning media. For such an application, it has also been found to be desirable to provide a watt density of 35 watts per gallon of cleaning media. Although other operating ranges could be used. For instance, as tube diameters increase above 4 feet, it may be desirable to operate in the 55-60 watts per gallon range to reach the inside of the tube bundles or to remove a disproportionate amount of sticky or compacted contaminants. The longer a heat exchanger is in use between cleaning cycles the more desirable it may be to increase the watts per gallon used to operate at a higher cleaning efficiency with respect to a given period of time.

The novel heat exchangers, which are further illustrated herein, efficiently utilize 35 watts per gallon to clean the tube bundles positioned therein. It should be noted, however, that the designers of conventional heat exchangers did not anticipate the novel use of thickness mode ultrasonics to clean heat exchanger components. Hence, with conventional heat exchangers it may be necessary to increase the watts per gallon above 35 watts per gallon in a given cleaning operation. It should be noted that inputting less than 35 watts per gallon could also be utilized. However, such lower input power may not always clean stubborn contaminates.

It should be noted at the outset that the drawing shown in FIG. 1 is provided for exemplary purposes only to describe general aspects of what is claimed herein. Neither FIG. 1, nor any of the drawings, should be construed as limiting what is claimed in any way. For instance, shell 12 can comprise many different constructions and configurations. Shell 12 can be made of a variety of different materials, such as metals, composites, plastics, and the like. Shell 12 can be different shapes, such as circular, oval, square, rectangular, hexagonal, and the like. As will be discussed further herein, shell 12 in one example comprises an open top cleaning tank sufficiently shaped and dimensioned to accommodate an industrial heat exchanger. In another example, shell 12 comprises a cleaning tank with a top that enclose space 14 during a cleaning operation. In a further example, shell 12 comprises the actual shell of a heat exchanger.

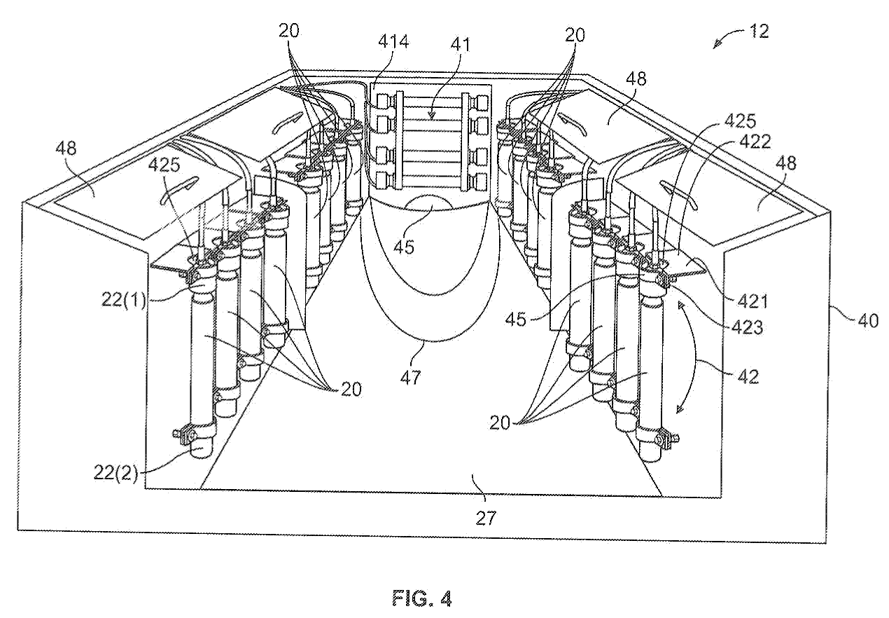

Referring now to FIG. 4, in one embodiment shell 12 comprises an open topped generally rectangular tank 40. Attached to tank 40 is a plurality of PushPull® thickness mode transducers 20 arranged in parallel to each other. The majority of PushPull® thickness mode transducers 20 shown in FIG. 4 are configured such that they extend vertically from the floor 27 of tank 40 in the direction of an opening 41 at the top of the tank 40. For illustrative purposes, however, one grouping of PushPull® thickness mode transducers 20 is shown arranged horizontally with respect to floor 25. As has been discussed herein, multiple configurations are possible. For instance, PushPull® thickness mode transducers 20 can be arranged in horizontal, vertical, and even diagonal configurations, and combinations thereof. Further, depending on the application, different sizes of PushPull® thickness mode transducers 20 can be utilized. For instance, if it were desirable to generate a large amount of excitation in the middle of the tank, corresponding PushPull® thickness mode transducers 20 could be made larger in diameter than other PushPull® thickness mode transducers 20 positioned in the tank. As another alternative two generators, one connected to each end 22(1), 22(2) of the center PushPull® thickness mode transducers 20 could be utilized to add additional excitation to certain portions of tank 40.

PushPull® thickness mode transducers 20 are in one example attached to tank 40 through utilization of bracket mechanisms 42. Bracket mechanisms 42 in one example comprise plate 421 having horizontally projecting portion 422 and vertically projecting portion 423. Horizontally projecting portion 422 includes recess 425 to receive both top portion 22(1) of PushPull® thickness mode transducer 20 and electric cabling which is connected to a generator (not shown). Brackets 45 are attached with screws to vertically projecting portion 423 and bear against top portion 21(1) of PushPull® thickness mode transducer 20 to secure it to the sidewall of tank 40. Bracket mechanisms 42 also secure bottom portion 22(1) of PushPull® thickness mode transducers 20 to sidewall of tank 40. Hinged access doors 48 can be added to tank 40 to aid in the insertion of PushPull® thickness mode transducers 20 prior to operation and the removal of PushPull® thickness mode transducers 20 subsequent to operation. It should be noted that bracket mechanism 42 is depicted and described for exemplary purposes only. Alternate means of attaching PushPull® thickness mode transducers 20 to tank 40 can be utilized without departing from the scope of what is described and claimed herein.

In a further embodiment, tank 40 could be provided with a reflector that would enhance the distribution of sound throughout the tank. Such a reflector would be particularly effective in cases in which there is not a uniform distance between the PushPull® thickness mode transducers 20 and the exterior surface of tank 40. In one embodiment, the reflector is fabricated from 14 gauge steel and includes two opposing sidewalls that are spaced approximately 2 inches apart to form an air gap there between. The reflector in one example is removably or permanently fixed to the tank 40 through conventional connecting mean. For long tanks 40, the reflector could be provided in multiple segments that would be fastened together prior to the cleaning process.

Referring further to FIG. 4, tank 40 includes a drainage opening 45. Opening 45 can be used to drain cleaning media from tank 40 when the media becomes saturated with impurities to the extent that its cleaning effectiveness is reduced beyond an acceptable level. To assist in the drainage of cleaning media, portion 47 of the floor 27 of tank 40 is sloped towards opening 45. In one example, portion 47 is sloped at an angle of approximately eleven degrees or more, although an angle of more than or less than eleven degrees can work.

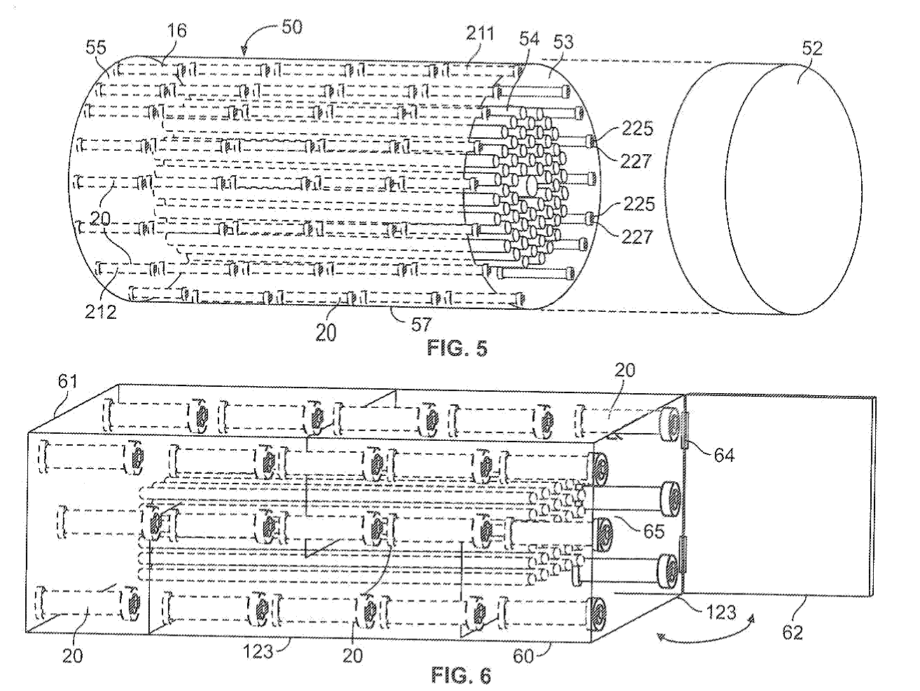

Referring now to FIG. 5, in another embodiment, shell 12 comprises a tank 50 having a circular cross section. Tank 50 includes a lid 52, which can be utilized to cover an opening 53 of tank 50 when the unit is in operation. A tube bundle 54 can be removed from a heat exchanger and placed within tank 50. Piezoelectric components 16 are attached to tank 50 such that they extend in a direction perpendicular to a plane of opening 53 such that they will run in a direction parallel to tube bundle 54.

In the example shown, piezoelectric components 16 comprise PushPull® thickness mode transducers 20, although other transducers, such as immersibles could also be used. In one example, some PushPull® thickness mode transducers 20 are attached to the tank in the following manner: A plurality of recesses are formed at one end 55 of the tank such that one end a PushPull® thickness mode transducers 20 can be seated therein. On the other end 57 of tank 50, PushPull® thickness mode transducers 20 can be secured by inserting interface 225 and projection 227 into a corresponding recess (not shown) on lid 52. On both ends 55, 57 the other end of the piezoelectric transducer 20, i.e., the end not inserted into a recess, can be secured through means, such as bracket mechanism 42 or conventional means. In one example, there are also piezoelectric transducers 20 located in the interior of shell 12 that can be attached through bracket mechanism 42 or conventional means. As an alternative to the embodiment shown in FIG. 5, all transducers 20 are attached through a bracket mechanism or conventional means. It should further be noted that accommodation for electrical cabling can be made by providing holes in shell 12 that are sealed around the cabling to prevent leakage.

In operation, a cleaning media is added to the tank 50 and the piezoelectric PushPull® thickness mode transducers 20 are actuated in the manner described with respect to FIG. 1. In on example, end 57 of tank 50 is elevated, for example by 5-10 degrees, and the chemistry of the cleaning media, as it is energized by the PushPull® thickness mode transducers 20 causes contaminants to stick together and move down the pipes to toward the one end 55 of tank 50.

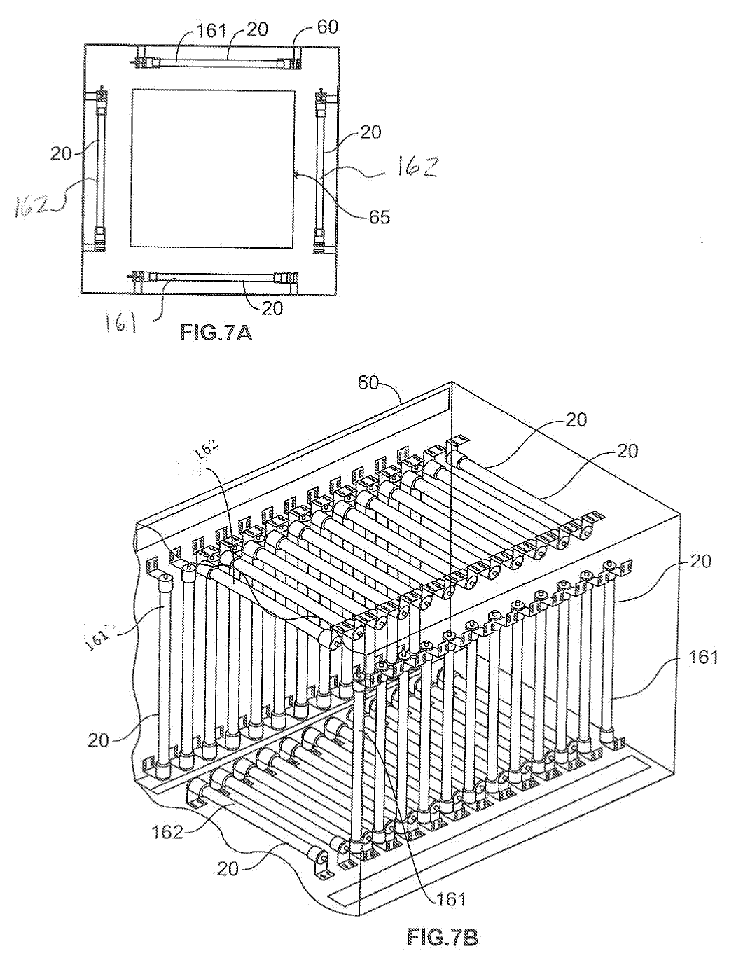

Referring now to FIGS. 6 through 8, in other embodiments, rather than attaching transducer components 16 to a tank, enhanced heat exchanger designs are provided in which the shell, sleeve, or frame of the heat exchanger itself is expanded to accommodate the positioning of transducer components 16 directly into the heat exchanger. In other words, shell 12 of FIG. 1 is the shell of the heat exchanger and the heat exchanger component 1 is the heat exchanger interior. To clean the heat exchanger, cleaning media is placed within shell by placing the heat exchanger in a tank filled with cleaning media and actuating thickness mode piezoelectric transducer components 16. In another embodiment, the cleaning media is added directly to the interior of the heat exchanger where it would reside in a self-contained manner. Piezoelectric transducer components 16 can be added to the heat exchanger before cleaning, and removed after cleaning.

In the embodiment of FIG. 6, shell 12 is heat exchanger shell 60 (or sleeve or frame), which in the example shown, has a rectangular cross-section. Shell 60 is shaped and dimensioned such that end plates 61, 62 are enlarged such that they provide clearance for piezoelectric transducer components 16 to be attached directly shell 60. In one example, the shell has a width between opposing sides of at least two (2) feet. In one embodiment, piezoelectric components 16 are PushPull® thickness mode transducers 20 that attached to the heat exchanger shell 60 in the same manner as described with respect to FIG. 5. Similarly accommodation can be made for electrical cabling, such as sealed holes. In another embodiment, piezoelectric transducer components 16 are immersible thickness mode transducers 30, which are attached through available means, such as brackets, screws, welding, etc. End plate 62 includes a hinge 64 connecting it to shell 60 such that end plate 62 acts as an access door for insertion and removal of PushPull® thickness mode transducers 20. It should be noted that the hinged relationship of end plate 62 to shell 60 is described for illustrative purposes only. In other embodiments, an access opening or access door could be provided on another location of heat exchanger shell 60. Piezoelectric transducers are actuated to clean tube handle 65.

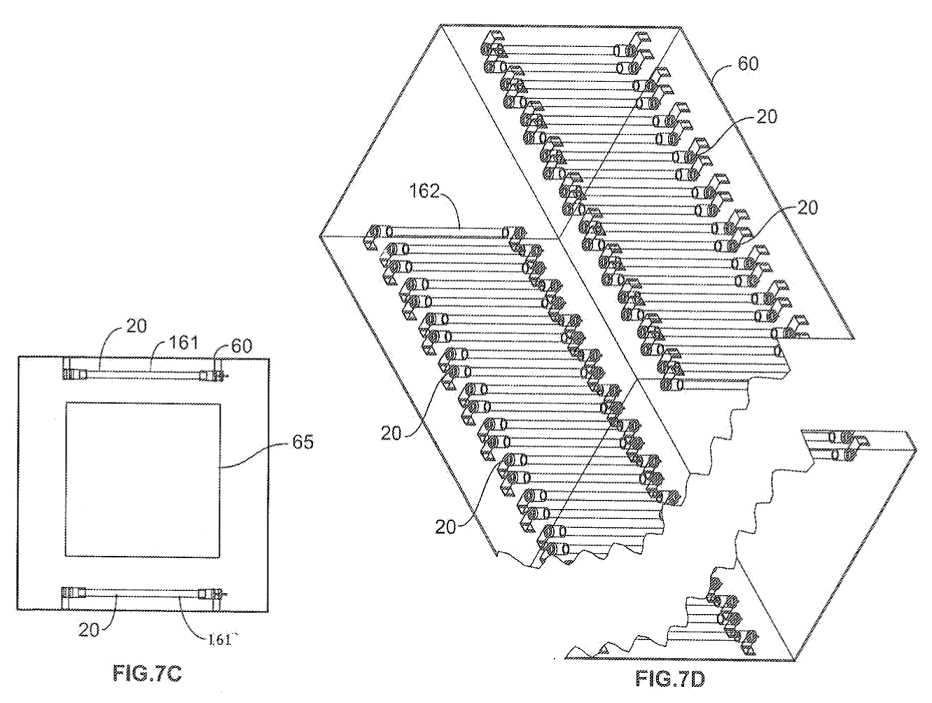

Referring now to FIGS. 7A-7D, in other embodiments of heat exchanger 60, rather than arranging PushPull® thickness mode transducers 20 such that they extend parallel to the direction of the heat exchanger tubes in tube bundle 65, PushPull® thickness mode transducers 20 are shown arranged in opposing pairs 161, 162, in a spaced apart configuration, on planes perpendicular to the tubes 65 of the heat exchanger 60. In the embodiment shown in FIGS. 7A and 7B, PushPull® thickness mode transducers 20 are shown for illustrative purposes to surround tube bundle 65 on four sides. In another embodiment, shown in FIGS. 7C-7D PushPull® thickness mode transducers 20 are shown on two sides of tube bundle 65.

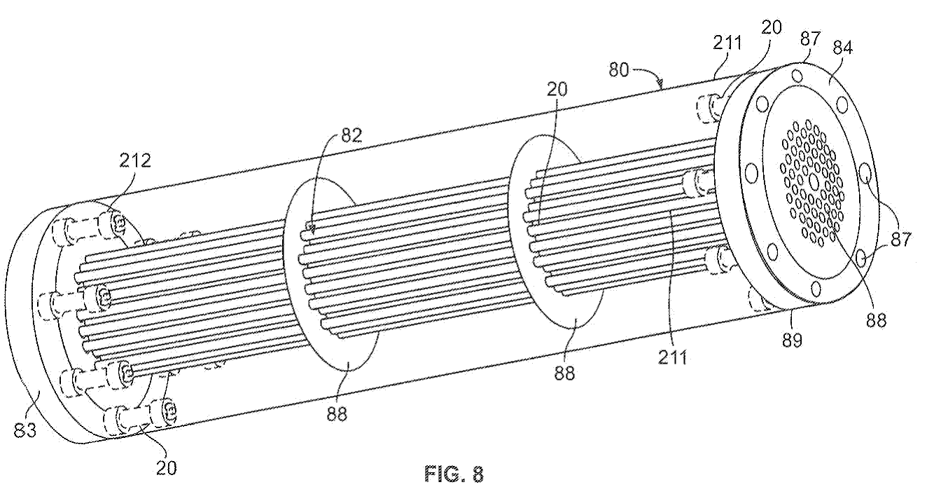

Referring now to FIG. 8, in another embodiment, shell 12 is a circular shell and tube heat exchanger 80. In one example, shell and tube heat exchange 80 has a diameter of at least 2 feet. Heat exchanger 80 includes a tube bundle 82 positioned between two opposing end plates 83, 84. A plurality of piezoelectric transducer components 16 are positioned between the end plates 83, 84. In one example, piezoelectric transducer components 16 are PushPull® thickness mode transducers 20. In another example, piezoelectric transducer components 16 are immersible thickness mode transducers.

Referring further to FIG. 8, in one example, end plates 83, 84 each include a plurality of recesses 87 (not shown on plate 83). The recesses on plate 83 correspond to recesses on plate 84. Each pair of recesses 87 is employed to receive an end 211, 212 of a PushPull® thickness mode transducer 20 in a manner similar as shown with respect to described in FIG. 5. In this manner, PushPull® thickness mode transducers 20 are secured within the body of heat exchanger 80. Fixture plates also include a plurality of recesses 88 to receive tubes from tube bundle 82. Furthermore, in the example shown, due to the length of the heat exchanger 80 additional support is provided by the utilization of intermediate fixture plates 88. Fixture plates 88 include a plurality of holes through which the tubes in tube bundle 82 pass. Fixture plates 68 also allow fluid or air to pass such that that heat exchange media is allowed to pass freely through heat exchanger and associate with the fluid or air within tube bundle 82. Additional thickness mode transducers 20 (not shown) can also be positioned between end plates 83, 84 and fixed to shell of heat exchanger in a manner already described herein with respect to FIG. 5. Further, access doors can be provided as described with respect to FIG. 6. Fixture plates 88 provide an intermediate base of support for PushPull® thickness mode transducers 20. Additional conventional fixturing can also be used to secure and support transducers 20.

Referring further to FIG. 8, in a further embodiment, a PushPull® thickness mode transducer 89 is positioned in the center of tube bundle 82. Such a PushPull® thickness mode transducer 89 can be utilized to radiate ultrasonic energy outward from the center tube bundle 82, thereby improving cleaning efficiency. In one embodiment, the PushPull® thickness mode transducer 89 is has a diameter that is up to three times as large as the diameter of the heat exchanger tubes. For instance, if the heat exchanger tubes were 1 inch, the PushPull® thickness mode transducer 89 would be 3 inches.

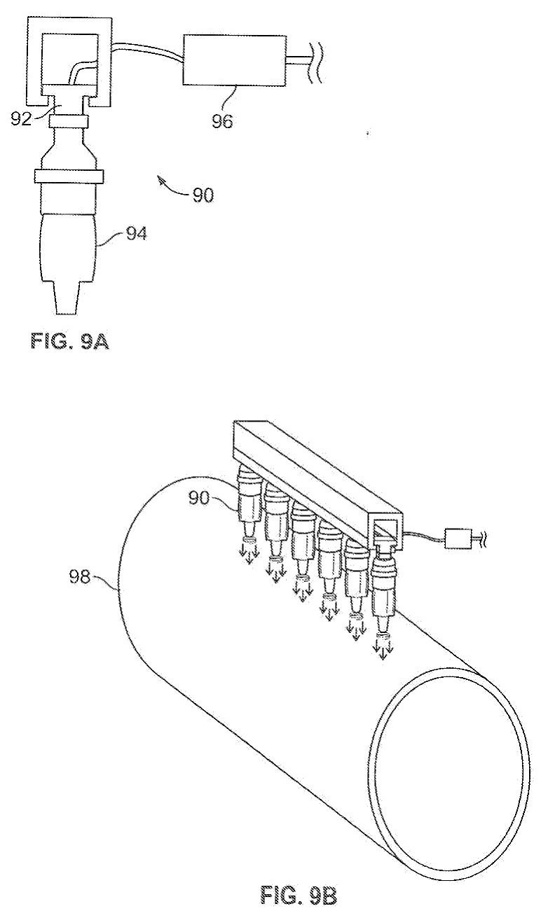

Referring to FIG. 9, in another embodiment, piezoelectric components 16 comprise an ultrasonic welding device 90. Ultrasonic welding device comprises thickness mode ultrasonic converter 92 connected to a horn 94. The thickness mode ultrasonic converter 92 is connected to a generator 96. The ultrasonic generator 96 is electrically coupled to the thickness mode ultrasonic converter 92. When generator 96 applies power to thickness mode ultrasonic converter 92, electrical energy is converted to mechanical energy, which radiates in a concentrated form as ultrasonic waves from horn 94. Referring to FIG. 9B, a heat exchanger component 1, such as a tube bundle 98 can be positioned within a cleaning tank, with or without cleaning media, or on a cleaning surface and one or more ultrasonic welding device 90 can be passed over the heat exchanger component 1. In one example, the horn 94 is shaped and dimensioned to match the contour of the heat exchanger component 1. For instance, in one test, an entire heat exchanger shell was cleaned by placing the heat exchanger in a tank and using a plurality of horns 94 with a width of 2″ and an arch of 6″.

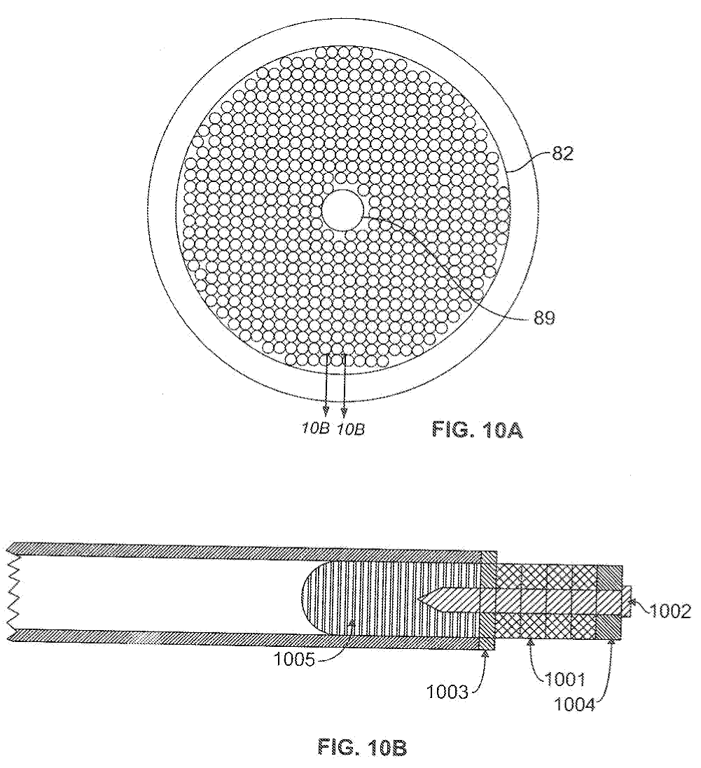

Referring to FIGS. 10A and 10B in a further embodiment, thickness mode piezoelectric components 16 are inserted within heat exchanger tubes and are utilized to direct ultrasonic energy through the inside of the heat exchanger tubes and thereby remove contaminates from the sidewalls of the heat exchanger tube. FIG. 10A is a cross-sectional view taken along line 10A-10A in FIG. 8. FIG. 10B shows a cross-sectional view taken along line 10B-10B of the heat exchanger tube shown in FIG. 10A. A sectional view of a thickness mode piezoelectric component 16 is shown partially inserted into the tube. Thickness mode piezoelectric components 16 in one example comprise a thickness mode stacking of ultrasonics components 1001 connected by a connector 1002, such as a screw, between a two support masses 1003, 1004. Similar to the device shown in FIG. 9, a horn 1005 is attached to support mass 1003. An ultrasonic generator (not shown) is electrically coupled to the thickness mode stacking 1001. When the generator applies power to the thickness mode stacking 1001, electrical energy is converted to mechanical energy, which radiates in a concentrated form as ultrasonic waves from horn 1005. The high intensity thickness mode ultrasonic energy generated therefrom removes contaminates from the sidewalls of the tubes. Such a cleaning operation can take place in tank, with or without cleaning media, or on a cleaning surface.

While particular embodiments have been shown and described, it will be apparent to those skilled in the art that changes and modifications may be made without departing from the broader aspects of applicants' contribution. The actual scope of the protection sought is intended to be defined in the following claims when viewed in their proper perspective based on the prior art.

1. A heat exchanger, comprising:
a shell defining a space and having a first end, a second end, and at least two opposing sides, wherein the shell is adapted to hold a cleaning media;
a heat exchanger component positioned within the space; and
at least one thickness mode transducer positioned within the space, wherein when the space holds a cleaning media, the thickness mode transducer is capable of imparting ultrasonic energy to the heat exchanger component through the cleaning media.

2. The heat exchanger of claim 1, wherein the heat exchanger component is a heat exchanger tube bundle.

3. The heat exchanger of claim 1, wherein the heat exchanger component is a heat exchanger comprising a shell and a tube bundle in assembled form.

4. The heat exchanger of claim 1, wherein the at least one thickness mode transducer is removably connected to the shell.

5. The heat exchanger of claim 1, wherein the at least one thickness mode transducer is a thickness mode immersible ultrasonic transducer.

6. The heat exchanger of claim 1, wherein the heat exchanger component comprises a tube bundle and the tube bundle includes a plurality of heat exchanger tubes arranged in parallel with respect to each other.

7. The heat exchanger of claim 6, wherein the at least one thickness mode transducer comprises a rod shaped push-pull thickness mode transducer.

8. The heat exchanger of claim 7, wherein the rod shaped push-pull thickness mode transducer, has a first end attached to one opposing side of the shell and a second end attached to the other opposing side of the shell.

9. The heat exchanger of claim 8, wherein the push-pull thickness mode transducer is arranged in a plane perpendicular to the plurality of heat exchanger tubes.

10. The heat exchanger of claim 7, wherein the rod shaped push-pull thickness mode transducer has a first end and a second end, and further wherein the rod shaped push-pull thickness mode transducer includes a first thickness mode transducer element positioned on the first end of the rod shaped push-pull transducer.

11. The heat exchanger of claim 10, wherein the first thickness mode transducer element has a thickness of about two tenths (0.2) of an inch.

12. The heat exchanger of claim 11, wherein the first thickness mode transducer element comprises a plurality of constituent elements.

13. The heat exchanger of claim 12, wherein the plurality of constituent elements have a uniform thickness.

14. The heat exchanger of claim 13, wherein the plurality of constituent elements have a shape selected from at least one of circular or rectangular.

15. The heat exchanger of claim 14, wherein the plurality of constituent elements are stacked to provide thickness mode vibration when actuated.

16. The heat exchanger of claim 10, wherein the rod shaped push-pull thickness mode transducer includes a second thickness mode transducer element positioned on the second end.

17. The heat exchanger of claim 1, wherein the at least one thickness mode transducer comprises a plurality of rod shaped push-pull thickness mode transducers.

18. The heat exchanger of claim 17, wherein at least one of the plurality of rod shaped push-pull thickness mode transducers has a larger diameter than other of the plurality of rod shaped push-pull thickness mode transducers.

19. The heat exchanger of claim 17, wherein each of the first end and the second end of the shell have a generally circular cross-section and the heat exchanger tubes are arranged parallel to each other and in a generally cylindrical formation.

20. The heat exchanger of claim 19, wherein the plurality of rod shaped push-pull thickness mode transducers are arranged in parallel to and circumferentially around the heat exchanger tubes.

21. The heat exchanger of claim 17, wherein the at least two opposing sides of the shell comprise first opposing sides and second opposing sides, and the heat exchanger tubes are parallel to each other and in a generally cubic formation.

22. The heat exchanger of claim 21, wherein the plurality of rod shaped push-pull thickness mode transducers comprise a plurality of thickness mode transducer pairs.

23. The heat exchanger of claim 22, wherein a plurality of thickness mode transducer pairs are connected in opposition between the first opposing sides.

24. The heat exchanger of claim 23, wherein a plurality of thickness mode transducer pairs are connected in opposition between the second opposing sides.

25. The heat exchanger of claim 24, wherein the plurality of thickness mode transducer pairs extend from the first end of the shell to the second end of the shell.

26. The heat exchanger of claim 1, wherein the shell has a length defined as a distance between the first end and the second end and a width defined as a distance between the opposing sides.

27. The heat exchanger of claim 26, wherein the width is equal to a distance of at least two feet.

28. The heat exchanger of claim 1, wherein the heat exchanger is an industrial heat exchanger of a shape and dimension sufficient for utilization in an oil and gas refinery.

29. The heat exchanger of claim 28, wherein the industrial heat exchanger is utilized in at least one industry segment selected from the group consisting of: chemical, fertilizer, food and dairy, organic batch processing, petrochemical, pharmaceutical and biotech, and pulp and paper.

30. The heat exchanger of claim 29, wherein the industrial heat exchanger is utilized in oil and gas refineries.

31. The heat exchanger of claim 30, wherein the petrochemical industry heat exchanger comprises a shell and tube heat exchanger.

32. The heat exchanger of claim 31, wherein the shell and tube heat exchanger has a diameter of at least 2 feet.

33. The heat exchanger of claim 1, wherein the thickness mode transducer has a thickness (t) which is directly proportional to a resonant frequency of the piezoelectric transducer.

34. The heat exchanger of claim 1, wherein the space defined by the shell has a top side and a bottom side.

35. The heat exchanger of claim 34, wherein the at least one thickness mode transducer extends from the top side to the bottom side.

36. A method of cleaning a heat exchanger component, the method comprising:
selecting a heat exchanger component for cleaning;
placing the heat exchanger component in a tank;
filling the tank with a cleaning media.
connecting at least one thickness mode transducer to the cleaning tank; and
operating the at least one thickness mode transducer.

37. The method of claim 36, further comprising:
removing the cleaning media from the tank;
removing the at least one thickness mode transducer from the cleaning tank;
refilling the cleaning tank with the cleaning media; and
reconnecting the at least one thickness mode transducer to the cleaning tank; and
operating the at least one thickness mode transducer to clean the heat exchanger component.

38. The method of claim 36, further comprising:
selecting the at least one thickness mode transducer to be an immersible thickness mode piezoelectric transducer.

39. The method of claim 36, further comprising:
selecting the cleaning media to be a fluid having a substantially alkaline chemistry.

40. The method of claim 36, further comprising
selecting the cleaning media to be a fluid having a substantially neutral chemistry.

41. The method of claim 36, wherein the step of operating the at least one thickness mode transducer comprises utilizing the at least one thickness mode transducer to generate at least 35 watts of power per gallon of cleaning media.

42. The method of claim 36, wherein the step of selecting the heat exchanger component comprises selecting at least one of:
(i) a plurality of heat exchanger tubes; and
(ii) a heat exchanger shell.

43. The method of claim of claim 42, further comprising selecting heat exchanger tubes that have been utilized in an oil or gas refining process such that the heat exchanger tubes have been fouled with bitumen residue.

44. The method of claim 42, wherein the heat exchanger tubes have a diameter of about 0.5 inch to 1 inch.

45. The method of claim 42, further comprising:
selecting the cleaning tank such that it has a cylindrical shape and dimension.

46. The method of claim 45, wherein the cylindrical shape and dimension includes:
a first portion and a second portion, wherein the first portion is removable from the second portion; and
the second portion defines a reservoir for receipt of cleaning media.

47. The method of claim 46, wherein the step of placing comprises:
positioning the heat exchanger tubes in the reservoir.

48. The method of claim 47, wherein the step of positioning at least one thickness mode transducer in the cleaning tank comprises:
mounting a plurality of rod shaped push-pull thickness mode transducers within the second portion of the cleaning tank.

49. The method of 48, wherein the step of mounting comprises:
mounting the rod shaped push-pull thickness mode transducers in a substantially parallel relationship to the heat exchanger tubes.

50. The method of claim 48, wherein the rod shaped push-pull thickness mode transducers each comprise a first end and a second end.

51. The method of claim 50, wherein each of the rod shaped push-pull thickness mode transducers have a transducer element positioned on the first end.

52. The method of claim 51, wherein each of the rod shaped push-pull thickness mode transducers have a transducer element positioned on the second end.

53. A method of cleaning a component through utilization of an ultrasonic cleaning unit, the ultrasonic cleaning unit comprising a frame having a first end and a second end, two opposing sides, an opening positioned between the first side and second opposing sides, and at least one thickness mode transducer connected to the frame within the opening, the method comprising:
placing a component in a cleaning tank;
filling the tank with cleaning media;
positioning the frame within the cleaning tank; and
operating the at least one thickness mode transducer to clean the component.

54. The method of claim 53, wherein the tank comprises a sidewall having first and second opposing sides and a bottom surface, the method of positioning the frame comprising:
positioning the frame such that the frame is in contact with the bottom surface.

55. The method of claim 53, wherein the step of operating comprises:
providing at least 35 watts of power per gallon of cleaning media.

56. A transducer immersion unit, comprising:
a frame comprising a sidewall having a first end, a second end, at least two opposing sides, and an axis extending through the first end and the second end;
an opening defined in the sidewall and extending from the first end to the second end, wherein the opening is coaxial to the frame;
at least one thickness mode transducer positioned on the frame within the opening.

57. The transducer immersion unit of claim 56, wherein the first end and the second end have a circular cross-section.

58. The transducer immersion unit of claim 56, wherein the first end and the second end are rectangular in cross-section.

59. The transducer immersion unit of claim 56, wherein the first end and the second end are square in cross-section

60. The transducer immersion unit of claim 56, wherein the at least two opposing sides comprise:
first opposing sides and second opposing sides.

61. The transducer immersion unit of claim 56, wherein the at least one thickness mode transducer comprises a plurality of rod shaped push-pull thickness mode transducers.

62. The transducer immersion unit of claim 61, wherein the plurality of rod shaped push-pull thickness mode transducers comprises a plurality of thickness mode transducer pairs.

63. The transducer unit of claim 62, wherein the plurality of thickness mode transducers pairs are positioned in opposition to each other on the first opposing sides.

64. The transducer unit of claim 63, wherein the plurality of thickness mode transducer pairs are further positioned in opposition to each other on the second opposing sides.

65. The transducer unit of claim 64, wherein the plurality of thickness mode transducer pairs are positioned such that they extend from the first end to the second end of the immersion unit.

66. A method of cleaning a heat exchanger component, comprising:
selecting at least one thickness mode ultrasonic energy generating device including an ultrasonic converter and a horn attached to the ultrasonic converter, wherein the horn is adapted to transmit ultrasonic energy from the converter;
selecting the horn to match a surface contour of the heat exchanger component;
attaching the thickness mode ultrasonic energy device to an external shell of a heat exchanger component; and
actuating the thickness mode ultrasonic energy generating device such that ultrasonic energy is directed from the horn to at least one portion of the heat exchanger component.

67. The method of claim 66, wherein the step of selecting the at least one ultrasonic wave generating device comprises:
selecting a plurality of thickness mode ultrasonic energy generating devices.

68. The method of claim 67, further comprising:
coupling the plurality of thickness mode ultrasonic energy generating devices together such that their respective horns are arranged generally parallel with respect to each other.

69. The method of claim 68, wherein the step of actuating comprises:
actuating the plurality of thickness mode ultrasonic energy generating devices such that ultrasonic energy is directed from the respective horns to respective portions of the heat exchanger component.

70. The method of claim 68, further comprising:
moving the plurality of thickness mode ultrasonic energy generating over the surface of the heat exchanger component.

71. A method of cleaning a heat exchanger tube, comprising:
selecting at least one thickness mode ultrasonic energy generating device including an ultrasonic converter and a horn attached to the ultrasonic converter, wherein the horn is adapted to transmit ultrasonic energy from the converter;
selecting the horn to fit within the heat exchanger tube
placing the heat exchanger tube in a cleaning tank filled with cleaning media;
positioning the horn within the heat exchanger tube; and
actuating the thickness mode ultrasonic energy generating device such that ultrasonic energy is directed throughout the heat exchanger tube.
